(19) United States
(12) Patent Application Publication
(10) Pub. No.: US 2012/0068211 A1
(43) Pub. Date: Mar. 22, 2012

(54) LED PACKAGE STRUCTURE

(75) Inventor: TSONG-SING WU, NEW TAIPEI CITY (TW)

(73) Assignee: YU-HUI CHEN, NEW TAIPEI CITY (TW)

(21) Appl. No.: 13/018,647

(22) Filed: Feb. 1, 2011

(30) Foreign Application Priority Data
Sep. 21, 2010 (TW) 099218244

(51) Int. Cl. H01L 33/52

(52) U.S. Cl. 257/98; 257/E33.059

(57) ABSTRACT

An LED (light-emitting diode) package structure includes a substrate, at least one LED unit disposed on the substrate for generating a light beam, and an optical correcting element disposed within a travelling path of the light beam. The optical correcting element includes a transparent body disposed on and cooperating with the substrate to define a reception chamber with an opening for access into the reception chamber and a transparent encapsulated body injected into the reception chamber via the opening for encapsulating the LED unit therewithin.

This application claims the benefits of the Taiwan Patent Application Serial No. 099218244 filed on Sep. 21, 2010, the subject matter of which is incorporated herein by reference.

### BACKGROUND OF THE INVENTION

1. Field of the Invention

The present invention relates to a package structure, more particularly to an LED (light-emitting diode) package structure.

2. Description of the Prior Art

According to the prior art technique, an LED (light-emitting diode) package structure generally includes a substrate, an LED unit and an encapsulated body. During the manufacturing process, the LED unit is disposed on the substrate firstly. Then, a mold is mounted in such a manner to enclose the LED unit, after which, an encapsulating material is injected into the mold in order to encapsulate the LED unit therein. Upon removal of the mold, the LED (light-emitting diode) package structure is obtained.

However, there always remain a gap or clearance between the substrate and the mold such that the encapsulating material leaks out from the mold during the injection process such that upon removal of the LED (light-emitting diode) package structure from the mold, there remains some extra material around the periphery of the encapsulated body, thereby causing poor quality of the LED (light-emitting diode) package structure.

### SUMMARY OF THE INVENTION

Therefore, the object of the present invention is to provide an LED (light-emitting diode) package structure, which includes an optical correcting element. The optical correcting element is composed of a transparent body and a transparent encapsulated body, which cooperatively enhance the quality of the light beam generated by an LED unit employed therein.

The LED (light-emitting diode) package structure according to the present invention includes a substrate, at least one LED (light-emitting diode) unit and an optical correcting element. The LED (light-emitting diode) unit is posed on the substrate for generating a light beam. The optical correcting element is disposed within a travelling path of the light beam to correct or alter the travelling path of the light beam. The optical correcting element includes a transparent body and a transparent encapsulated body. The transparent body is disposed on and cooperates with the substrate to define a reception chamber with an opening for access into the reception chamber. An encapsulating substance is injected into the reception chamber via the opening for encapsulating the LED unit therewithin and thus forming the transparent encapsulated body.

In one embodiment of the present invention, the transparent body has a correcting section projecting transversely into the travelling path of the light beam. To be more specific, the correcting section is selected from a group composed of a transparent concave lens, a transparent convex lens, a prism projecting upward from an even plain, a prism projecting inward from an even plain or a combination of the former elements.

Since the optical correcting element is composed of the transparent body and the transparent encapsulated body, the optical quality of the LED package structure of the present invention is enhanced. In addition, the encapsulating substance is injected into the reception chamber via the opening for forming the transparent encapsulated body and without the need for removing the mold enclosing the former. In other words, the manufacturing process of the LED package structure of the present invention is simplified since there is no need of removing the mold and since no leakage of the encapsulating substance is caused during the injection process.

### BRIEF DESCRIPTION OF THE DRAWINGS

Other features and advantages of this invention will become more apparent in the following detailed description of the preferred embodiments of this invention, with reference to the accompanying drawings, in which:

FIG. 1 is a perspective view of an LED (light-emitting diode) package structure of the present invention;

FIG. 2 is a cross-sectional view of the LED package structure of the present invention taken along lines A-A in FIG. 1;

FIG. 3 is a cross-sectional view of the LED package structure of the present invention, wherein the LED package structure is provided with a correction section for correcting a traveling path of a light beam generated by an LED unit employed therein; and

FIG. 4 shows a product within which the LED package structure of the present invention is implemented.

### DETAILED DESCRIPTION OF THE PREFERRED EMBODIMENTS

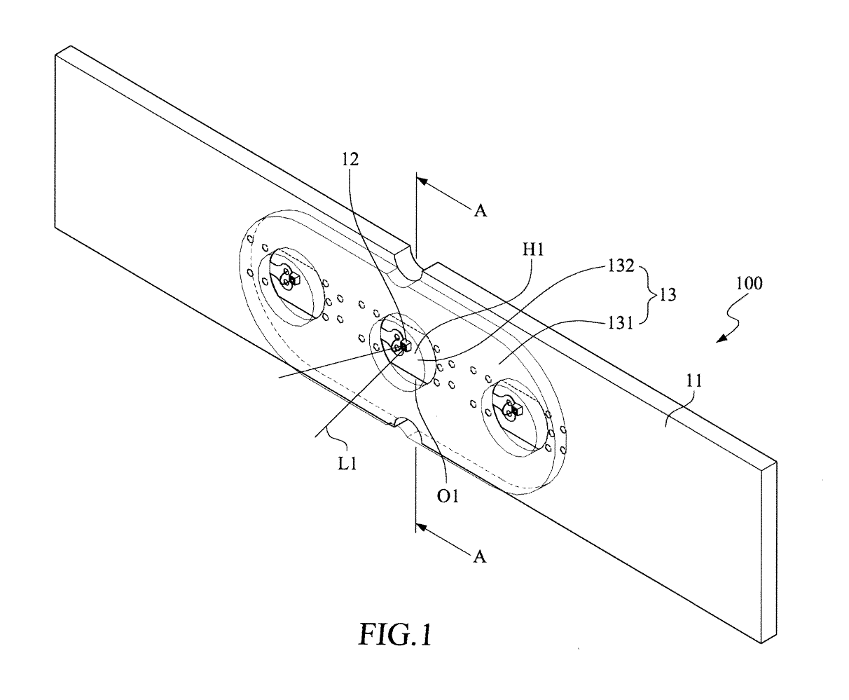

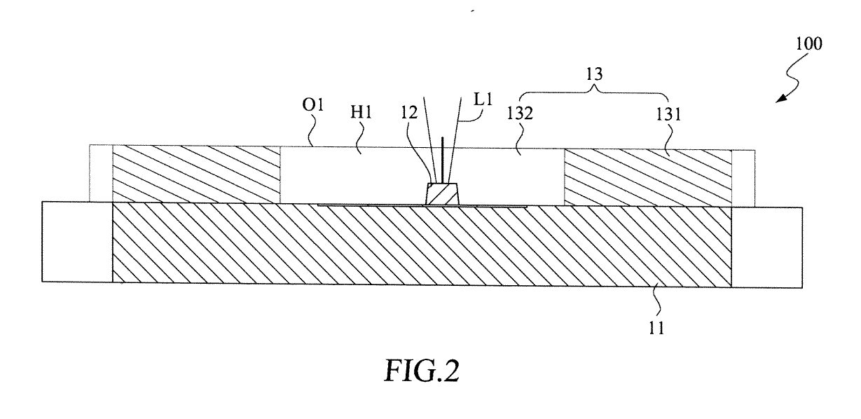

Referring to FIGS. 1 and 2, wherein FIG. 1 is a perspective view of an LED (light-emitting diode) package structure of the present invention while FIG. 2 is a cross-sectional view of the LED package structure of the present invention taken along the lines A-A in FIG. 1. As illustrated, the LED package structure 100 of the present invention includes a substrate 11, at least one LED (light-emitting diode) unit 12 and an optical correcting element 13.

The LED (light-emitting diode) unit 12 is mounted on the substrate 11 for generating a light beam L1.

The optical correcting element 13 is disposed within a travelling path of the light beam L1, and includes a transparent body 131 and a transparent encapsulated body 132.

The transparent body 131 is mounted on and cooperates with the substrate 11 to define a reception chamber H1 with an opening O1 for access into the reception chamber H1. During the manufacturing process, an encapsulating material, such transparent adhesive substance, is injected into the reception chamber H1 via the opening O1 for forming the transparent encapsulated body 132 such that after solidification, the LED unit 12 is encapsulated within the transparent encapsulated body 132.

Note in FIG. 1, the traveling path of the light beam L1 of LED unit 12 passes through the transparent encapsulated body 132. In order to enhance the color of the light beam L1 generated by the LED unit 12, some phosphor powder or other light-exciting powder (or material) can be added into the transparent encapsulated body 132 during the manufacturing process, thereby adjusting or enhancing the colors of the light beam L1.

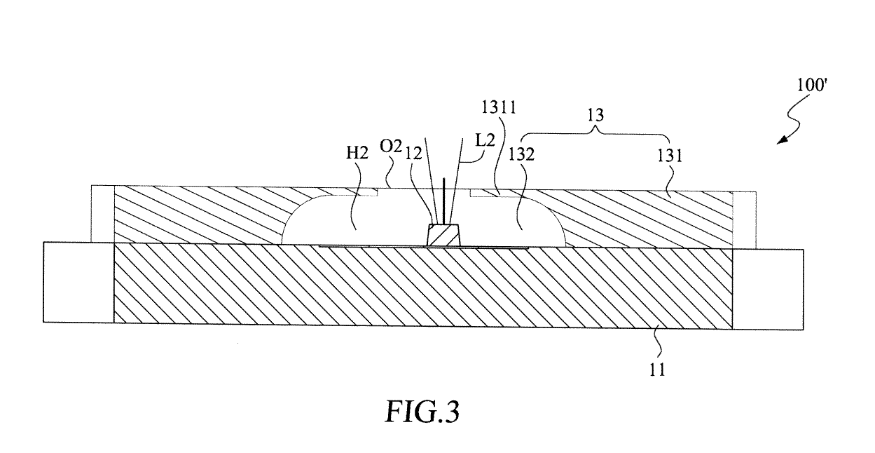

FIG. 3 is a cross-sectional view of another LED package structure 100′ of the present invention, wherein the LED package structure 100′ has the structure similar to the previous embodiment except that the present embodiment is provided with two correction sections 1311 projecting into the opening O2 from the periphery defining the opening O2 for correcting the traveling path of the light beam L1 generated by the LED unit 12 employed therein. Of course, the dimension or size of the opening O2 may not be the same as the opening O1 and the position of the opening O2 is not only intended immediately right above the LED unit 12. The position of the opening O2 can be located at a lateral side of the LED unit 12. Alternately, the shape or structure of the correction section 1311 can be in the form of a concave lens, a convex lens, and a prism projecting upward from an even plain, a prism projecting inward from an even plain or a combination of the former elements. The structure of the reception chamber H2 can be altered in order to complement with the changes of the shape of the correction section 1311 so as to adjust the traveling path of the light beam L2, hence altering the traveling path of the light beam L2 of the optical correcting element 13.

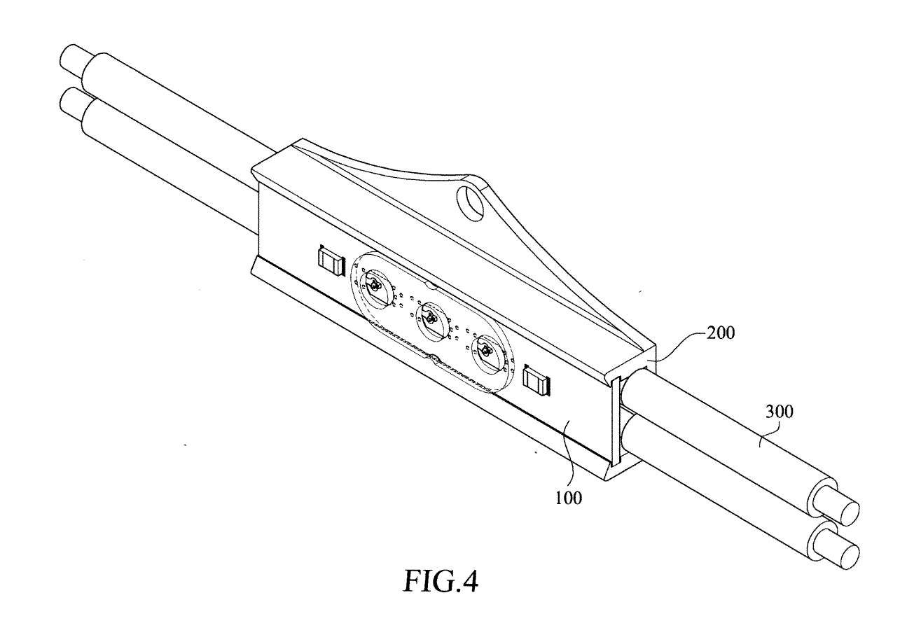

FIG. 4 shows a product within which the LED package structure of the present invention is implemented. As illustrated, the LED package structure 100 is sandwiched securely between a frame 200 and a power cable 300 is disposed behind the frame 200 and is electrically coupled to a plurality of the LED package structures 100 in series such that the product may serve as an advertising board with the LED package structures 100 of the present invention providing the requirement illumination.

As explained above, since the optical correcting element 13 is composed of the transparent body 131 and the encapsulated body 132, and since the encapsulating substance is injected into the reception chamber H1 via the opening O1, there is no leakage problem of the injected encapsulating material from the reception chamber H1 for forming the encapsulated body 132 and the mold is not required to be removed from the transparent body 131 after the injection process. Thus, the optical quality of the LED package structure of the present invention is enhanced. In other words, the manufacturing process of the LED package structure of the present invention is simplified since there is no need of removing the mold and since no leakage of the encapsulating substance is caused during the injection process.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An LED (light-emitting diode) package structure comprising:
a substrate;
at least one LED (light-emitting diode) unit disposed on said substrate for generating a light beam; and
an optical correcting element disposed within a travelling path of said light beam, said optical correcting element including
a transparent body disposed on and cooperating with said substrate to define a reception chamber with an opening for access into said reception chamber, and
a transparent encapsulating material injected into said reception chamber via said opening for forming a transparent encapsulated body and encapsulating said LED unit therewithin.

2. The LED package structure according to claim 1, wherein said transparent body further has a correcting section projecting into said travelling path of said light beam.

3. The LED package structure according to claim 2, wherein said correcting section is selected from a group composed of a transparent concave lens, a transparent convex lens, a prism projecting upward from an even plain, a prism projecting inward from an even plain or a combination of the former elements.
